(19) United States
(12) Patent Application Publication
(10) Pub. No.: US 2010/0282603 A1
(43) Pub. Date: Nov. 11, 2010

(54) HEATED SUBSTRATE SUPPORT FOR CHEMICAL VAPOR DEPOSITION

(75) Inventors: William N. Sterling, Santa Clara, CA (US); John M. White, Hayward, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/845,563

(22) Filed: Jul. 28, 2010

Related U.S. Application Data
(62) Division of application No. 11/143,992, filed on Jun. 2, 2005, now abandoned.
(60) Provisional application No. 60/588,663, filed on Jul. 16, 2004.

(51) Int. Cl. C23C 14/34; C23F 1/00; C23C 16/44; B29C 65/00

(52) U.S. Cl. 204/298.02; 204/298.31; 156/345.51; 118/715; 156/293

(57) ABSTRACT

A method and apparatus for making a heated substrate support assembly used in a processing chamber is provided. The processing chamber includes a substrate support assembly, having a first plate and a second plate with grooves disposed therein for receiving one or more heating elements, and a power source for heating the substrate support assembly. A first surface of the first plate and a second surface of the second plate include one or more matching structures disposed thereon, such that both plates can be compressed together by isostatic compression and form into a plate-like structure for supporting a substrate during substrate processing. In another embodiment, the first and second plates are compressed by applying pressure all around. In still another embodiment, compressing the first and second plates is performed at elevated temperature.

### CROSS-REFERENCE TO RELATED APPLICATIONS

This application is a divisional application of the co-pending U.S. patent application Ser. No. 11/143,992, filed Jun. 2, 2005, which claims benefit of U.S. Provisional Patent Application Ser. No. 60/588,632, filed Jul. 16, 2004. All the aforementioned patent applications are incorporated by reference.

### BACKGROUND OF THE INVENTION

1. Field of the Invention

Embodiments of the present invention generally relate to processing of a substrate, and more particularly to a substrate support assembly for heating a substrate in a chemical vapor deposition chamber. More specifically, the invention relates to methods and apparatus for substrate processing at high temperatures. In addition, other embodiments of the present invention may be used, for example, in physical vapor deposition (PVD), etching, and other processes to deposit, alloy, etch, or anneal substrate materials.

2. Description of the Related Art

Chemical vapor deposition (CVD) is a process to deposit a thin film layer onto a substrate. In general, the substrate is supported in a vacuum deposition process chamber, and the substrate is heated to a high temperature, such as several hundred degrees Centigrade. Deposition gases are injected into the chamber, and a chemical reaction occurs to deposit a thin film layer onto the substrate. The thin film layer may be a dielectric layer, a semiconductor layer, or a metal layer. The deposition process may be plasma enhanced (PECVD) or thermally enhanced (thermal CVD).

Liquid crystal displays or flat panels are commonly used for active matrix displays such as computer and television monitors. In general, PECVD is employed to deposit a thin film on a transparent glass substrate (for a flat panel) by introducing a precursor gas or gas mixture into a vacuum chamber that contains the flat panel. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the flat panel that is positioned on a temperature controlled substrate support. Volatile by-products produced during the reaction are pumped from the chamber through an exhaust system.

Flat panels are typically large, often exceeding 370 mm×470 mm and ranging over 1 square meter in size. Large area substrates that are 4 square meters or larger are envisioned in the near future. Typically, a substrate support structure, such as a susceptor, a heater pedestal, and the like, is employed to hold a substrate, and typically includes a plate-like structure mounted on a stem for the substrate to be placed thereon, along with a lift assembly for raising and lowering the substrate to processing and non-processing positions within the vacuum process chamber. Also, a heating element is embedded within the plate-like structure to facilitate substrate processing and heating.

Large gas distribution plates utilized for flat panel processing have a number of fabricating problems that result in high manufacturing costs. For example, the substrate support structure is generally constructed of aluminum, an aluminum alloy, or ceramic material to take advantage of these materials' high corrosion resistance and high thermal conductivity properties. However, between the heating element and the materials that make up portions of the substrate support structure there is poor thermal conductivity and corrosion resistance so that undesirable warping of the substrate support structure and uneven heating of the substrate can be observed after the substrate support structure is manufactured.

In addition, thermal expansion characteristics of the various materials for various portions/parts of the substrate support structure must be compensated for in the design and manufacturing of the substrate support structure. For example, some materials readily available for making the substrate support structure may be hard and brittle, making them difficult to machine, and they may easily crack from thermal shock if repeatedly subjected to a sufficient thermal gradient. Cracking may also arise from the differential thermal expansion at the transition interface of different materials with different thermal expansion coefficients used as parts/portions of the substrate support structure. Even joining parts fabricated from the same material is a challenge because many assembly methods and devices used to assemble different material parts for the substrate support structure, such as welding, bolting, brazing, forging, and screwing, may be unreasonably difficult or unreliable. Further, other problems involve the high cost required for purchasing the materials of the heating element and various portions of the substrate support structure and for manufacturing the substrate support structure.

Achieving temperature uniformity is another concern with substrate support structures having heaters operated at high temperatures in substrate processing systems. As is well known, deposition and etch rates are affected by the temperature of the substrate. Therefore, a temperature differential across the surface of a substrate support structure holding a substrate may result in differential depositions or etches. Some conventional heater and substrate support structure designs do not evenly distribute heat across the substrate. This problem may become more pronounced at higher temperatures, where thermal gradients may be greater.

Therefore, there is a need for an improved substrate support that reduces the manufacturing cost, and has good deposition and substrate heating performance.

### SUMMARY OF THE INVENTION

Embodiments of the invention provide a substrate support assembly for heating a substrate in a processing chamber. In one embodiment, a substrate support assembly for a processing chamber is provided. The substrate support assembly includes a first plate having a substrate contacting surface and a first surface, and a second plate having a second surface. The first surface includes a first set of one or more grooves disposed thereon and the second surface comprising a second set of one or more grooves disposed thereon. The substrate support assembly further includes one or more heating elements disposed in between the first plate and the second plate, wherein the first plate and the second plate are adhered to each other and the first set of the one or more grooves are aligned with the second set of the one or more grooves for receiving the one or more heating elements. Also, the first and the second plate further includes one or more first structures and one or more second structures, respectively, to be aligned and matched together during the manufacturing of the substrate support assembly. In another embodiment, the first plate and a second plate are pressed together by isostatic compression at a temperature of about 20° C. or higher.

In another embodiment, an apparatus for processing a substrate is provided. The apparatus includes a processing chamber, a substrate support assembly disposed in the processing chamber and adapted to support the substrate thereon, and a gas distribution plate assembly disposed in the processing chamber to deliver one or more process gases above the substrate support assembly. The substrate support assembly comprising a first plate and a second plate and one or more heating elements disposed in between the first plate and the second plate, wherein the first plate and the second plate are adhered to each other.

In another embodiment, a method of manufacturing a substrate support assembly having a plate-like structure is provided. The plate-like structure includes a first plate and a second plate. The method includes matching the first plate and the second plate together for forming the plate-like structure, applying pressure all around and surrounding the plate-like structure by isostatic compression, and compressing the first plate and the second plate into the plate-like structure. In one aspect, the first plate and the second plate are compressed into the plate-like structure by a hot isostatic press or a cold isostatic press, such as at a temperature of about 20° C. or higher. In another aspect, the first plate and the second plate are compressed by applying high pressure surrounding the plate-like structure. Preferably, a pressure of about 100,000 psi or higher can be applied.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a cross-sectional schematic view of a bottom gate thin film transistor.

FIG. 2A is a cross-sectional schematic view of an illustrative processing chamber having one embodiment of a substrate support assembly of the invention.

FIG. 2B depicts a cross-sectional schematic view of one embodiment of a substrate support assembly of the invention.

FIG. 2C depicts a cross-sectional schematic view of a portion of a substrate support assembly according to one embodiment of the invention.

FIG. 2D depicts a cross-sectional schematic view of a portion of a substrate support assembly according to another embodiment of the invention.

FIG. 3 depicts a vertical cross-sectional schematic view of one embodiment of compressing a substrate support assembly.

FIG. 4A depicts a horizontal sectional top view of one embodiment of a substrate support assembly having heating elements therein.

FIG. 4B depicts a horizontal sectional view of another embodiment of a substrate support assembly having heating elements therein.

### DETAILED DESCRIPTION

The invention generally provides a substrate support assembly for providing uniform heating within a processing chamber. The invention is illustratively described below in reference to a chemical vapor deposition system configured to process large area substrates, such as a plasma enhanced chemical vapor deposition (PECVD) system, available from AKT, a division of Applied Materials, Inc., Santa Clara, Calif. However, it should be understood that the invention has utility in other system configurations such as etch systems, other chemical vapor deposition systems and any other system in which substrate heating within a process chamber is desired, including those systems configured to process circular substrates.

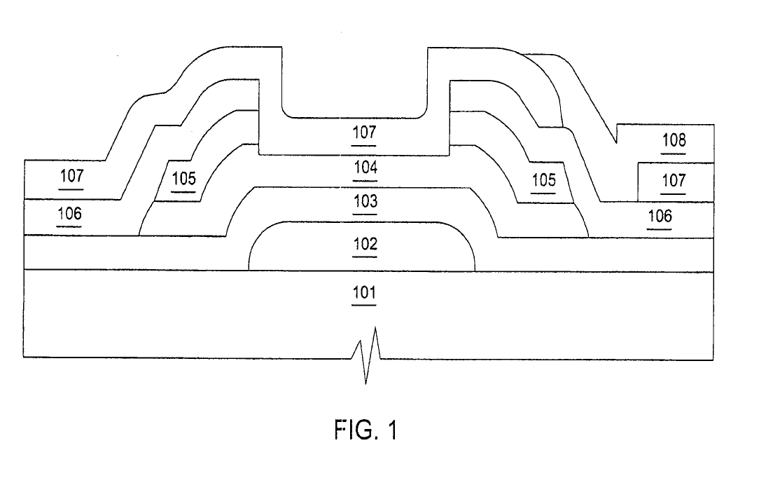

FIG. 1 illustrates a cross-sectional schematic view of a thin film transistor (TFT) structure. A common TFT structure is the back channel etch (BCE) inverted staggered (or bottom gate) TFT structure shown in FIG. 1. The BCE process is preferred, because the gate dielectric (SiN), and the intrinsic as well as n+ doped amorphous silicon films can be deposited in the same PECVD pump-down run. The BCE process shown here involves only 4 patterning masks. The substrate 101 may comprise a material that is essentially optically transparent in the visible spectrum, such as, for example, glass or clear plastic. The substrate may be of varying shapes or dimensions. Typically, for TFT applications, the substrate is a glass substrate with a surface area greater than about 500 mm². A gate electrode layer 102 is formed on the substrate 101. The gate electrode layer 102 comprises an electrically conductive layer that controls the movement of charge carriers within the TFT. The gate electrode layer 102 may comprise a metal such as, for example, aluminum (Al), tungsten (W), chromium (Cr), tantalum (Ta), or combinations thereof, among others.

The gate electrode layer 102 may be formed using conventional deposition, lithography and etching techniques. Between the substrate 101 and the gate electrode layer 102, there may be an optional insulating material, for example, such as silicon dioxide (SiO₂) or silicon nitride (SiN), which may also be formed using an embodiment of a PECVD system described herein. The gate electrode layer 102 is then lithographically patterned and etched using conventional techniques to define the gate electrode.

A gate dielectric layer 103 is formed on the gate electrode layer 102. The gate dielectric layer 103 may be silicon dioxide (SiO₂), silicon oxynitride (SiON), or silicon nitride (SiN), deposited using an embodiment of a PECVD system according to this invention. The gate dielectric layer 103 may be formed to a thickness in the range of about 100 Å to about 6000 Å.

A bulk semiconductor layer 104 is formed on the gate dielectric layer 103. The bulk semiconductor layer 104 may comprise polycrystalline silicon (polysilicon) or amorphous silicon (α-Si), which could be deposited using an embodiment of a PECVD system incorporating this invention or other conventional methods known to the art. Bulk semiconductor layer 104 may be deposited to a thickness in the range of about 100 Å to about 3000 Å.

A doped semiconductor layer 105 is formed on top of the semiconductor layer 104. The doped semiconductor layer 105 may comprise n-type (n+) or p-type (p+) doped polycrystalline (polysilicon) or amorphous silicon (α-Si), which could be deposited using an embodiment of a PECVD system incorporating this invention or other conventional methods known to the art. Doped semiconductor layer 105 may be deposited to a thickness within a range of about 100 Å to about 3000 Å. An example of the doped semiconductor layer 105 is n+ doped α-Si film. The bulk semiconductor layer 104 and the doped semiconductor layer 105 are lithographically patterned and etched using conventional techniques to define a mesa of these two films over the gate dielectric insulator, which also serves as storage capacitor dielectric. The doped semiconductor layer 105 directly contacts portions of the bulk semiconductor layer 104, forming a semiconductor junction.

A conductive layer 106 is then deposited on the exposed surface. The conductive layer 106 may comprise a metal such as, for example, aluminum (Al), tungsten (W), molybdenum (Mo), chromium (Cr), tantalum (Ta), and combinations thereof, among others. The conductive layer 106 may be formed using conventional deposition techniques. Both the conductive layer 106 and the doped semiconductor layer 105 may be lithographically patterned to define source and drain contacts of the TFT.

Afterwards, a passivation layer 107 may be deposited. Passivation layer 107 conformably coats exposed surfaces. The passivation layer 107 is generally an insulator and may comprise, for example, silicon dioxide (SiO₂) or silicon nitride (SiN). The passivation layer 107 may be formed using, for example, PECVD or other conventional methods known to the art. The passivation layer 107 may be deposited to a thickness in the range of about 1000 Å to about 5000 Å. The passivation layer 107 is then lithographically patterned and etched using conventional techniques to open contact holes in the passivation layer.

A transparent conductor layer 108 is then deposited and patterned to make contacts with the conductive layer 106. The transparent conductor layer 108 comprises a material that is essentially optically transparent in the visible spectrum and is electrically conductive. Transparent conductor layer 108 may comprise, for example, indium tin oxide (ITO) or zinc oxide, among others. Patterning of the transparent conductive layer 108 is accomplished by conventional lithographical and etching techniques. The doped or un-doped (intrinsic) amorphous silicon (α-Si), silicon dioxide (SiO2), silicon oxynitride (SiON) and silicon nitride (SiN) films used in liquid crystal displays (or flat panels) could all be deposited using an embodiment of a plasma enhanced chemical vapor deposition (PECVD) system incorporating in this invention.

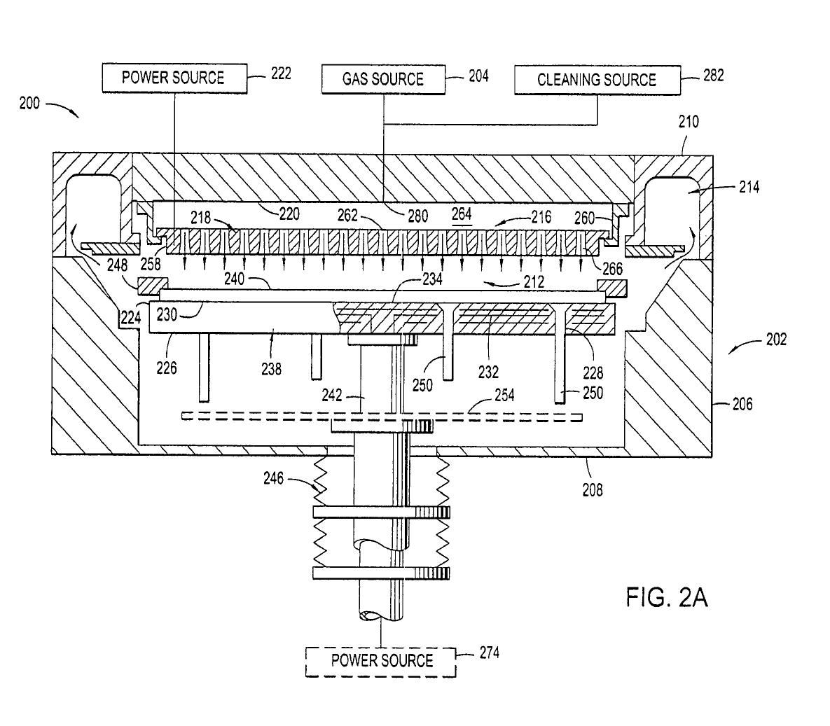

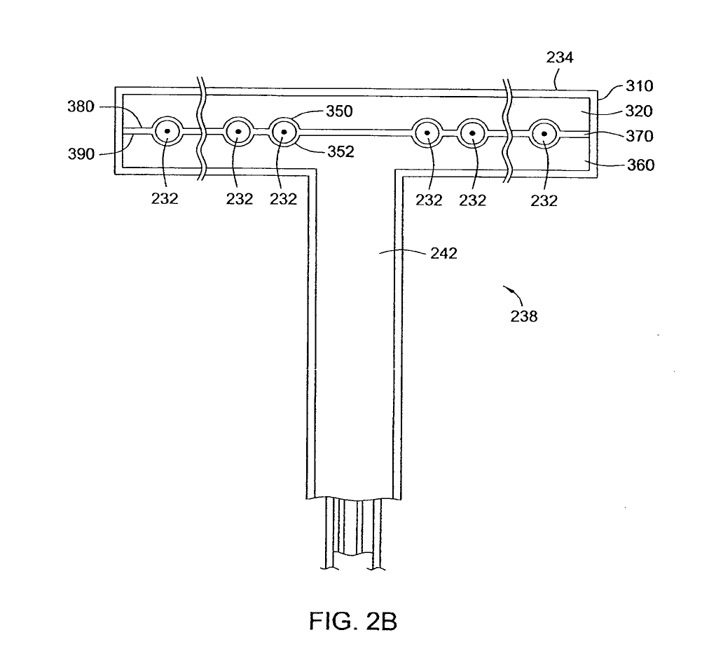

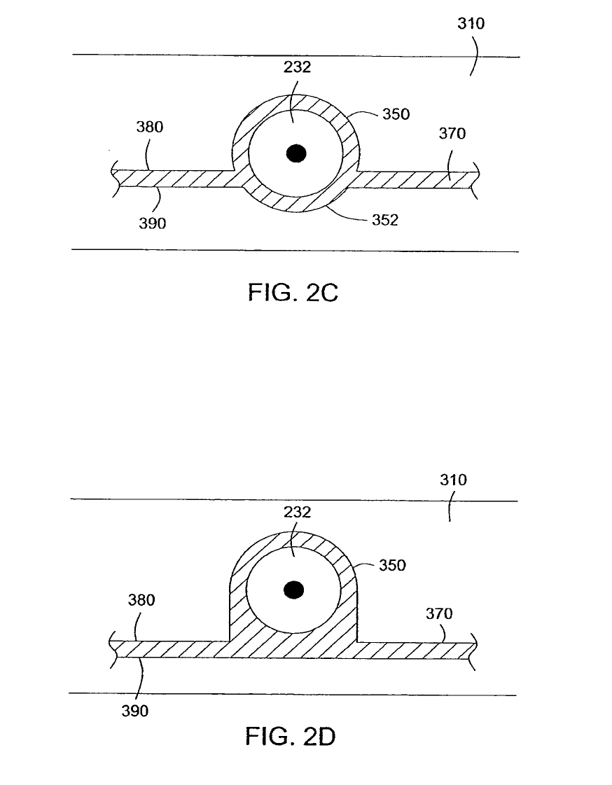

FIG. 2A is a cross-sectional schematic view of one embodiment of a plasma enhanced chemical vapor deposition system 200, available from AKT, a division of Applied Materials, Inc., Santa Clara, Calif. The system 200 generally includes a processing chamber 202 coupled to a gas source 204. The processing chamber 202 has walls 206 and a bottom 208 that partially define a process volume 212. The process volume 212 is typically accessed through a port (not shown) in a wall 206 that facilitates movement of a substrate 240 into and out of the processing chamber 202. The walls 206 and bottom 208 are typically fabricated from a unitary block of aluminum or other material compatible with processing. The walls 206 support a lid assembly 210 that contains a pumping plenum 214 that couples the process volume 212 to an exhaust port (that includes various pumping components, not shown). The pumping plenum 214, coupled to an external pumping system (not shown), is utilized to channel gases and processing by-products uniformly from the process volume 212 and out of the processing chamber 202.

A temperature controlled substrate support assembly 238 is centrally disposed within the processing chamber 202. The substrate support assembly 238 supports a substrate 240, such as a glass substrate and others, during processing. In one embodiment, the substrate support assembly 238 includes a body 224 that encapsulates one or more embedded heaters/heating elements 232. The body 224 is generally made of a thermally conductive material such as aluminum. Other materials known in the art, such as ceramic, can also be used.

The one or more heaters/heating elements 232, disposed in the substrate support assembly 238 and coupled to an optional power source 274, are generally made of a resistive element to controllably heat the substrate support assembly 238 and the glass substrate 240 positioned thereon to a predetermined temperature. Typically, in a CVD process, the one or more heating elements 232 maintain the glass substrate 240 at a uniform temperature of at least higher than room temperature, such as about 60 degrees Celsius or higher, typically at a temperature of about between about 150 degrees to at least about 460 degrees Celsius, depending on the deposition processing parameters for the material being deposited on the substrate.

Generally, the substrate support assembly 238 has a lower side 226 and a substrate contacting surface 234. The substrate contacting surface 234 supports the glass substrate 240. The lower side 226 has a stem 242 coupled thereto. The stem 242 couples the substrate support assembly 238 to a lift system (not shown) that moves the substrate support assembly 238 between an elevated processing position (as shown) and a lowered position that facilitates substrate transfer to and from the processing chamber 202. The stem 242 additionally provides a conduit for electrical and thermocouple leads between the substrate support assembly 238 and other components of the system 200. Substrate support assemblies that may be adapted to benefit from the invention are described in commonly assigned U.S. Pat. No. 5,844,205, issued Dec. 1, 1998 to White et al.; U.S. Pat. No. 6,035,101, issued Mar. 7, 200 to Sajoto et al., all of which are hereby incorporated by reference in their entireties.

A bellows 246 is coupled between substrate support assembly 238 (or the stem 242) and the bottom 208 of the processing chamber 202. The bellows 246 provides a vacuum seal between the chamber volume 212 and the atmosphere outside the processing chamber 202 while facilitating vertical movement of the substrate support assembly 238.

The substrate support assembly 238 generally is grounded such that RF power supplied by a power source 222 to a gas distribution plate assembly 218 positioned between the lid assembly 210 and substrate support assembly 238 (or other electrode positioned within or near the lid assembly of the chamber) may excite gases present in the process volume 212 between the substrate support assembly 238 and the distribution plate assembly 218. The RF power from the power source 222 is generally selected commensurate with the size of the substrate to drive the chemical vapor deposition process.

The substrate support assembly 238 additionally is circumscribed by a shadow frame 248. Generally, the shadow frame 248 prevents deposition at the edge of the glass substrate 240 and substrate support assembly 238 so that the substrate does not stick to the substrate support assembly 238. The substrate support assembly 238 has a plurality of holes 228 disposed therethrough that accept a plurality of lift pins 250. The lift pins 250 are typically comprised of ceramic or anodized aluminum. The lift pins 250 may be actuated relative to the substrate support assembly 238 by an optional lift plate 254 to project from the support surface 230, thereby placing the substrate in a spaced-apart relation to the substrate support assembly 238.

The lid assembly 210 provides an upper boundary to the process volume 212. The lid assembly 210 typically can be removed or opened to service the processing chamber 202. In one embodiment, the lid assembly 210 is fabricated from aluminum. The lid assembly 210 typically includes an entry port 280 through which process gases provided by the gas source 204 are introduced into the processing chamber 202. The entry port 280 is also coupled to a cleaning source 282. The cleaning source 282 typically provides a cleaning agent, such as disassociated fluorine, that is introduced into the processing chamber 202 to remove deposition by-products and films from processing chamber hardware, including the gas distribution plate assembly 218.

The gas distribution plate assembly 218 is coupled to an interior side 220 of the lid assembly 210. The gas distribution plate assembly 218 is typically configured to substantially follow the profile of the glass substrate 240, for example, polygonal for large area flat panel substrates and circular for wafers. The gas distribution plate assembly 218 includes a perforated area 216 through which process and other gases supplied from the gas source 204 are delivered to the process volume 212. The perforated area 216 of the gas distribution plate assembly 218 is configured to provide uniform distribution of gases passing through the gas distribution plate assembly 218 into the processing chamber 202.

The gas distribution plate assembly 218 typically includes a diffuser plate 258 suspended from a hanger plate 260. The diffuser plate 258 and hanger plate 260 may alternatively comprise a single unitary member. A plurality of gas passages 262 are formed through the diffuser plate 258 to allow a predetermined distribution of gas passing through the gas distribution plate assembly 218 and into the process volume 212. The hanger plate 260 maintains the diffuser plate 258 and the interior surface 220 of the lid assembly 210 in a spaced-apart relation, thus defining a plenum 264 therebetween. The plenum 264 allows gases flowing through the lid assembly 210 to uniformly distribute across the width of the diffuser plate 258 so that gas is provided uniformly above the center perforated area 216 and flows with a uniform distribution through the gas passages 262.

The diffuser plate 258 is typically fabricated from aluminum, anodized aluminum, stainless steel, nickel or other RF conductive material. The diffuser plate 258 is configured with a thickness that maintains sufficient flatness or as otherwise conformal across the aperture 266 as not to adversely affect substrate processing. In one embodiment the diffuser plate 258 has a thickness between about 1.0 inch to about 2.0 inches. The diffuser plate 258 could be circular for semiconductor wafer manufacturing or polygonal, such as rectangular, for flat panel display manufacturing.

Gas distribution plates that may be adapted to benefit from the invention are described in commonly assigned U.S. patent application Ser. No. 09/922,219, filed Aug. 8, 2001 by Keller et al.; 10/140,324, filed May 6, 2002; 10/337,483, filed Jan. 7, 2003 by Blonigan et al.; 10/417,592, filed Apr. 16, 2003 by Choi et al.; U.S. Pat. No. 6,477,980, issued Nov. 12, 2002 to White et al.; and all of which are hereby incorporated by reference in their entireties.

FIG. 2B shows an example of a substrate support assembly 238, including a plate-like structure 310 and a substrate contacting surface 234 for supporting a substrate, such as a glass panel, in the vacuum deposition process chamber. The plate-like structure 310 of the invention can be used for making the body 224 as shown in FIG. 2A. The plate-like structure 310 is made from at least two plates aligned and matched together. One embodiment of the invention provides the plate-like structure 310 manufactured into one whole unifying body from a base plate 360 and a top plate 320 that are matched and aligned for receiving the one or more heating elements 232 disposed in between the top plate 320 and the base plate 360. The plate-like structure 310 is made into one whole unifying body by pressure coming from all three dimensional directions, such as by placing the plate-like structure 310 inside a high pressure chamber.

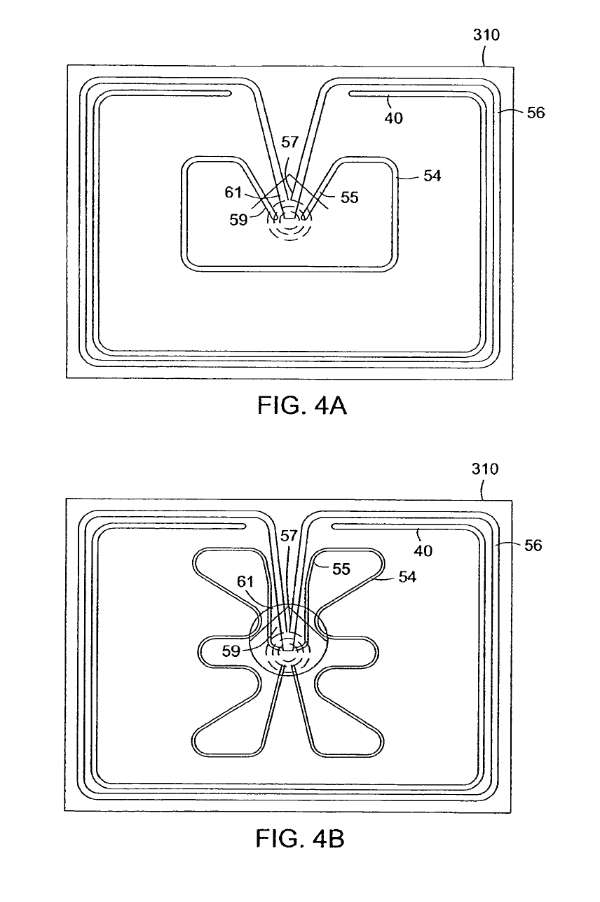

The top plate 320 of the plate-like structure 310 includes the substrate contacting surface 234 and a first surface 380 whereas the base plate 360 includes a second surface 390 engaging the first surface 380. The first surface on the top plate 320 and the second surface on the base plate 360 are matched and aligned such that the one or more heating elements 232, such as a pair of heating elements 54 and 56 as shown in FIGS. 4A and 4B are disposed between the first surface 380 of the top plate 320 and the second surface 390 of the base plate 360.

One or more heating elements 232 are disposed below the substrate contacting surface 234 of the plate-like structure 310. For example, two heating elements may be disposed beneath the surface of the plate-like structure 310 to surround the inner and outer portions of the substrate contacting surface 234 and distribute extensively to cover the substrate contacting surface 234, such as the two heating elements 54 and 56 as will be shown and described later in FIGS. 4A and 4B. The plate-like structure 310 can be attached to the stem 242 of the substrate support assembly. The plate-like structure 310 may be a rectangular shaped body fabricated of high purity aluminum or alloyed unanodized cast aluminum. However, other materials, such as ceramics, among others can also be used.

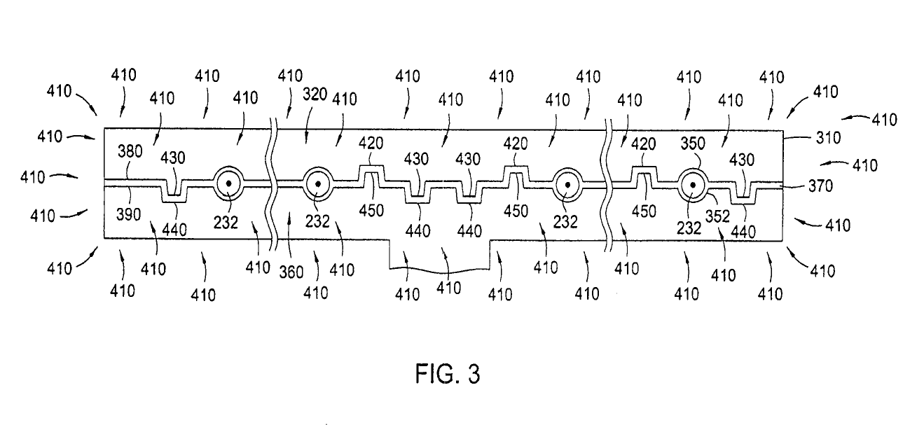

In addition, there is a compacted region 370 disposed between the base plate 360 and the top plate 320. Another embodiment of the invention provides that, during the manufacturing of the plate-like structure 310, the top plate 320 and the base plate 360 are compressed or compacted together by isostatic compression (as further described in FIG. 3) such that the compacted region 370 is evenly compacted, resulting in temperature uniformity across the substrate contacting surface 234 of the plate-like structure 310 when the plate-like structure 310 is heated.

The invention further provides one or more grooves, recesses, channels, other groove-like structures 350, 352 and the like formed on the first surface 380 or the second surface 390, respectively, for receiving the one or more heating elements 232. In one embodiment, both the first surface 380 and the second surface 390 may include groove-like structures 350, 352 aligned/matched for receiving the one or more heating elements 232 during the manufacturing of the plate-like structure 310 of the substrate support assembly 238. The groove-like structures 350, 352 are similar in construction, characterized by a generally semi-circular depression in the first surface 380 or second surface 390, or both. The invention also encompasses the groove-like structures 350 and/or the one or more heating elements 232 to be in other shapes and sizes.

Alternatively, as shown in FIG. 2C, the depths of the groove-like structures 350 on the first surface 380 and the matching groove-like structures 352 on the second surface 390 for receiving the one or more heating elements 232 may not be equally proportional. As a result, the depths of the groove-like structures on one surface are deeper than the depths of the groove-like structures on the matching surface. In other words, the majority of the heating elements 232 may be disposed on either the first surface 380, the second surface 390, or both.

In another embodiment, only one surface between the top plate 320 and the base plate 360 includes groove-like structures for receiving the one or more heating elements 232. As shown in FIG. 2D, the groove-like structure 350 on the first surface 380 is deep enough to surround and receive the one or more heating elements 232 and there is no matching groove-like structure on the second surface 390.

As mentioned earlier, problems in fabrication of large gas distribution plates utilized for flat panel processing result in high manufacturing costs. The manufacturing cost of the prior art substrate support assembly design is also relatively high. The assembly cannot be formed into one whole unifying body for the plate-like structure with uniform substrate heating profile so that heat can be evenly distributed surrounding the compacted region 370. For example, using prior art methods of brazing, welding, screwing, bolting, and forging the two plates together, the interface between the plates cannot be tightly compressed together, resulting in poor thermal contact among the heating elements, the top plate, and the bottom plate.

FIG. 3 is a partial sectional view of the substrate support assembly 238, demonstrating one embodiment of compression of the plate-like structure 310 of the invention. The substrate support assembly 238 having the plate-like structure 310 is shown with the stem 242 omitted in order to view the first surface 380 and the second surface 390 in the compacted region 370, and the one or more heating elements 232.

As shown in FIG. 3, the first surface 380 further includes one or more structures 420, 430 and the second surface 390 further includes one or more matching structures 440, 450. Each of the structures 420, 430, 440, and 450 can vary in shape without departing from embodiments of the invention and may be a structure of a recess, channel, protrusion, grooves, tongue, tooth, and the like, as long as they can be aligned and matched together along the first surface 380 and the second surface 390. In one embodiment, during manufacturing of the plate-like structure 310 of the substrate support assembly 238, the structures 420, 430 and the structures 440, 450 are aligned and matched together for ease of pressing the top plate 320 and the base plate 360 together and helping to form the plate-like structure 310 into a unifying body after isostatic compression.

In one embodiment of the invention, during manufacturing of the substrate support assembly 238, pressure 410 is applied all around the plate-like structure 310 for compacting the top plate 320 and the base plate 360 together through the use of structures 420, 430, 440, 450, such as grooves, channels, tongues, protrusions, recesses, teeth, among others. Thus, pressure 410 is surrounding the plate-like structure 310 from all three dimensional directions such that the plate-like structure 310 can be formed into one whole unifying body. Finally, a plate-like structure having one or more compressible heating elements therein is manufactured to any sizes and shapes of a substrate support assembly to be used in a vacuum deposition process chamber for heating a substrate with corresponding sizes and shapes. In an alternative embodiment, the heating elements 232 may be compressed into grooves located only in the top plate 320 or the base plate 360.

In another embodiment, the first surface 380 and the second surface 390 are pressed together by isostatic compression at a temperature of about 20° C. or higher. In still another embodiment, the first surface 380 and the second surface 390 are compressed by applying high pressure surrounding the whole body of the plate-like structure 310 from all directions. In addition, the compacted region 370, the space surrounding the one or more heating elements 232, and any other empty space in the substrate support assembly 238 may be filled with sand or other metal or ceramic powers or filling materials to be compacted and prevent the collapse of the plate-like structure 310 at high pressure during isostatic compression.

For example, a hot isostatic press can be used for manufacturing a plate-like structure 310. As another example, a cold isostatic press operating at lower temperature than the hot isostatic press can be used. In general, parts to be bonded together by an isostatic press are prepared and placed inside the isostatic press, which is similar to a high pressure chamber, or a furnace but allowing high pressure to be applied. The isostatic press may have an argon-rich atmosphere. Alternatively, other gas mixtures can be used to fill the space surrounding the parts to be compressed. The isostatic press can be heated up to a temperature of about 20° C. or higher, such as about 200° C. or higher and pressurized to a pressure of about 100 psi or higher, such as a pressure of about 100,000 psi or higher. In operation, the top plate 320 and the base plate 360, with the one or more heating elements and the filing materials of the compacted region 370 placed in between, are matched and aligned inside the argon-rich furnace for isostatic compression. Then, the plate-like structure 310 is formed into a unifying body inside the furnace under the above mentioned desired temperature and the desired pressure applied all around the whole body of the plate-like structure 310. Thus, there is no welding, bolting, brazing, forging, screwing, or any unidirectional force which may lead to uneven bonding between the top plate 320 and the base plate 360 of the formed plate-like structure, resulting in uneven thermal contact and temperature non-uniformity during the processing of substrates.

In use, the heating elements which were compressed according to the present invention were able to sustain heat densities in excess of 75 watts per inch. In addition, the plate-like structure 310 manufactured by the method of the invention can sustain a gap, interface, or compacted region 370 between the first surface 380 and the second surface 390 to compensate the thermal extension of the materials among portions/parts of the top plate 320 and the base plate 360 and thermal contact regions between the heating elements 232 and the top and base plates 320, 360.

The substrate support assembly 238 of the invention is easier to manufacture into a unifying plate-like structure with heating elements therein as compared to prior art designs. Therefore, the yield and cost of manufacturing the substrate support assembly would be improved. In addition to ease of manufacturing, the substrate support assembly 238 also has the benefit of uniform substrate heating profile resulting in improved device performance after substrate processing.

The invention contemplates that the locations of the heating elements 232 and the distribution of the structures 420, 430, 440, 450 in the top plate 320 and/or the base plate 360 are selected to provide an uniform substrate heating profile. For example, FIGS. 4A and 4B are horizontal sectional views of exemplary substrate support assemblies 238 having uniform substrate heating profiles. The heating elements 232 of the invention may include one or more heating elements, such as an inner heating element 54 and an outer heating element 56 as shown in FIGS. 4A and 4B and provided to run along inner and outer grooved regions of the plate-like structure 310. The inner heating element 54 and the outer heating element 56 are identical in construction, and only differ in length and positioning about the portion of the substrate support assembly 238. The inner heating element 54 and the outer heating element 56 may be manufactured inside the plate-like structure 310 to form into one or more heating element tubes 55, 57, 59 and 61 at the appropriate ends to be disposed within the hollow core of the stem 242. Each heating element and heating element tube includes a conductor lead wire or a heater coil embedded therein.

In addition, the routing of the inner heating element 54 and the outer heating element 56 in the plate-like structure 310 can be in dual loops that are somewhat generally parallel, as shown in FIG. 4A. Alternatively, the inner heating element, such as the heating element 54 can be in leaflet-like loops to somewhat evenly cover the surface of the plate-like structure. This dual loop pattern provides for a generally axially-symmetric temperature distribution across the plate-like structure 310, while allowing for greater heat losses at the edges of the surfaces.

The substrate support assembly 238 for display applications may be in square or rectangular shape, as shown herein in FIGS. 4A and 4B. Exemplary dimensions of a substrate support assembly 238 to support a substrate, such as a glass panel, may include a width of about 30 inches and a length of about 36 inches. However, the size of the plate-like structure of the invention is not limiting and the invention encompasses other shapes, such as round or polygonal. In one embodiment, the plate-like structure 310 is rectangular in shape having a width of about 26.26 inches and a length of about 32.26 inches or larger, which allows for the processing of a glass substrate for flat panel displays up to about 570 mm×720 mm or larger in size.

A generally axially-symmetric temperature distribution is characterized by a temperature pattern which is substantially uniform for all points equidistant from a central axis which is perpendicular to the plane of the substrate support assembly 238 and extends through the center of the substrate support assembly 238 parallel to (and disposed within) the stem 242 of the substrate support assembly 238. The inside and outside heating element loops may operate at different temperatures, the outside loops typically being operated at a higher temperature.

Under reduced gas pressure (vacuum) operating conditions, due to the thermal conduction between the heated substrate support assembly and a substrate resting atop, a uniform substrate temperature may not be created even if the heated support plate temperature is uniform. This is because, when heated, a substrate resting atop a heated substrate support assembly will experience increased heat losses at the edge portions of the substrate. Accordingly, a heated substrate support assembly having nearly uniform temperature distribution across its entire surface will not compensate for the uneven heat loss characteristics of the substrate. By operating the heating element in the outer loop at a higher temperature than the heating element in the inner loop, it is possible to compensate for the higher heat losses at the outermost or edge portions of the substrate. A substantially uniform temperature distribution is thus produced across the substrate in this fashion.

When the outer heating element 56 is operated at a higher temperature, there is a hot area in the plate-like structure 310 near outer loop of the heating element 56. One embodiment of the invention includes a structure 40, such as the structures 420, 430, 440, 450, e.g., grooves, channels, tongues, protrusions, recesses, teeth, etc., distributed near the inner portion of the outer heating element 56 and surrounding an outer portion of the substrate contacting surface 234. The structure 40 as shown in FIGS. 4A and 4B is contemplated to be positioned relatively near a hot area of the plate-like structure 310 to provide thermal resistance, compensate for thermal expansion differential, prevent warping of the plate-like structure 310, and improve overall temperature uniformity of the substrate support assembly.

Although several preferred embodiments which incorporate the teachings of the present invention have been shown and described in detail, those skilled in the art can readily devise many other varied embodiments that still incorporate these teachings. In addition, while the foregoing is directed to embodiments of the present invention, other and further embodiments of the invention may be devised without departing from the basic scope thereof, and the scope thereof is determined by the claims that follow.

1. A substrate support assembly for a processing chamber, comprising:
a first plate having a substrate contacting surface and a first surface, the first surface comprising a first set of one or more grooves formed thereon;
a second plate having a second surface, the second surface comprising a second set of one or more grooves formed thereon, the first plate and the second plate being pressed together by isostatic compression with the first set of the one or more grooves being aligned with the second set of the one or more grooves; and
one or more heating elements disposed in the aligned first set and second set of the one or more grooves between the first plate and the second plate.

2. The substrate support assembly of claim 1, wherein the first plate further comprises one or more first structures and the second plate further comprises one or more second structures such that the first structures are matched with the second structures.

3. The substrate support assembly of claim 2, wherein the first structures and second structures are selected from the group consisting of recesses, channels, protrusions, grooves, tongues, teeth, and combinations thereof.

4. The substrate support assembly of claim 2, wherein at least one of the matching first structures and second structures is located near an outer portion of the substrate contacting surface.

5. The substrate support assembly of claim 1, further comprising compacted filling materials between the first plate and the second plate.

6. The substrate support assembly of claim 1, wherein the one or more heating elements comprise an outer heating element and an inner heating element, the outer heating element operates at a higher temperature than the inner heating element.

7. An apparatus for processing a substrate, comprising:
a processing chamber;
a substrate support assembly disposed in the processing chamber and adapted to support the substrate thereon, the substrate support assembly comprising:
a first plate;
a second plate; and
one or more heating elements disposed in between the first plate and the second plate, wherein the first plate and the second plate being pressed together by isostatic compression; and
a gas distribution plate assembly disposed in the processing chamber to deliver one or more process gases above the substrate support assembly.

8. The apparatus of claim 7, wherein the first plate comprises a substrate contacting surface and a first surface, the second plate comprises a second surface, and one or more groove-like structures are formed either on the first surface or the second surface, or both for receiving the one or more heating elements.

9. The apparatus of claim 7, wherein the first plate further comprises one or more first structures and the second plate further comprises one or more second structures such that the first structures are matched with the second structures during isostatic compression.

10. The apparatus of claim 9, wherein the first structures and second structures are selected from the group consisting of recesses, channels, protrusions, grooves, tongues, teeth, and combinations thereof.

11. The apparatus of claim 9, wherein at least one of the matching first structures and second structures is located near an outer portion of the first plate and second plate.

12. The apparatus of claim 7, further comprising compacted filling materials between the first plate and the second plate.

13. The apparatus of claim 7, wherein the one or more heating elements comprise:
an outer heating element;
an inner heating element, wherein the outer heating element operates at a higher temperature than the inner heating element; and
a thermal resistance structure distributed near an inner portion of the outer heating element, wherein the thermal resistance structure is configured to compensate for thermal expansion differential, prevent warping of the plate-like structure, and improve overall temperature uniformity.

14. A method of manufacturing a substrate support assembly having a plate-like structure, the plate-like structure including a first plate with a substrate receiving surface and a first surface, and a second plate with a second surface, comprising:
aligning a first set of one or more groove-like structures on the first surface of the first plate with a second set of one or more groove-like structures on the second surface of the second plate;
receiving an inner heating element and an outer heating element in the aligned one or more groove-like structures;
matching the first surface of the first plate and the second surface of the second plate together for forming the plate-like structure; and
applying pressure all around and surrounding the plate-like structure by isostatic compression, wherein the first plate and the second plate are adhered to each other into the plate-like structure.

15. The method of claim 14, wherein the outer heating element operates at a higher temperature than the inner heating element.

16. The method of claim 15, further comprising forming a thermal resistance structure distributed near an inner portion of the outer heating element, wherein the thermal resistance structure is configured to compensate for thermal expansion differential, prevent warping of the plate-like structure, and improve overall temperature uniformity.

17. The method of claim 16, wherein the thermal resistance structure comprises one or more of grooves, channels, tongues, protrusion, recesses, and teeth.

18. The method of claim 14, wherein the applying pressure is performed in a high pressure furnace at a pressure of about 100,000 psi or higher.

19. The method of claim 18, wherein the applying pressure is performed at about 200° C. or higher

20. The method of claim 14, wherein the depth of the one or more groove-like structures on the first surface is greater than the depth of the one or more groove-like structures on the second surface.
